(19) United States
(12) Patent Application Publication
(10) Pub. No.: US 2026/0371497 A1
(43) Pub. Date: Nov. 19, 2026

(54) POWER MODULE, AIRCRAFT COMPRISING SUCH A POWER MODULE, AND METHOD FOR MANUFACTURING THE POWER MODULE

(71) Applicant: SAFRAN ELECTRICAL & POWER, Blagnac Cedex (FR)

(72) Inventors: Remy BIAUJAUD, Moissy-Cramayel (FR); Rachid SOUAHLIA, Moissy-Cramayel (FR)

(21) Appl. No.: 19/142,551

(22) PCT Filed: Dec. 20, 2023
(86) PCT No.: PCT/FR2023/052071

§ 371 Date: Jun. 23, 2025

(30) Foreign Application Priority Data
Dec. 28, 2022 (FR) FR2214573

(51) Int. Cl. H05K 3/28; H05K 1/181

(52) U.S. Cl. CPC H05K 3/285; H05K 1/181; H05K 2201/10015; H05K 2201/10022

(57) ABSTRACT

A power module having a substrate with an electrically insulating board and electrically conductive tracks; an electrical component secured against at least one of the electrically conductive tracks; a resistor secured against at least one of the electrically conductive tracks; a capacitor connected in series with the resistor; and an encapsulation. It furthermore includes two pins having bases secured to two of the conductive tracks, these bases being covered by the encapsulation, and free ends projecting outside the encapsulation; and the capacitor is placed outside the encapsulation and connected to the free ends of the pins.

### TECHNICAL FIELD OF THE INVENTION

This invention relates to a power module, an aircraft comprising such a power module and a method of manufacturing the power module.

### TECHNICAL BACKGROUND

The prior art discloses a power module comprising:
a substrate comprising:
   an electrically insulating plate with an upper face, and
   electrically conductive tracks extending over the upper face;
an electrical component secured against at least one of the electrical conductive tracks;
a resistor secured against at least one of the electrical conductive tracks;
a capacitor connected in series with the resistor; and
an encapsulation covering:
   at least a part of the electrical tracks,
   the electrical component.

In some power modules, the encapsulation covers the resistor and the capacitor. However, the capacitor is then subject to thermal and mechanical constraints present in the encapsulation, which requires the latter to be dimensioned accordingly. For example, the electrical component generally operates up to 175 °C, whereas a conventional capacitor only operates up to 125 °C. It is therefore necessary to provide a capacitor that operates at a higher temperature, and is therefore expensive.

In other power modules, the resistor and capacitor are placed outside the encapsulation. However, the resistor is no longer cooled by the substrate and therefore runs the risk of overheating, heating up the environment of the power module where sensitive electronics may be located.

It may therefore be desirable to provide a power module which avoids at least some of the above problems and constraints.

### SUMMARY OF THE INVENTION

A power module is therefore proposed:
a substrate comprising:
   an electrically insulating plate having an upper face, and
   electrically conductive tracks extending over the upper face;
an electrical component secured against at least one of the electrical conductive tracks;
a resistor secured against at least one of the electrical conductive tracks;
a capacitor connected in series with the resistor; and
an encapsulation covering:
   at least a part of the electrical tracks,
   the electrical component, and
   the resistor.
      characterized in that it further comprises:
two pins with:
   bases secured to two of the conductive tracks, these bases being covered by the encapsulation, and
   free ends projecting outside the encapsulation;
      in that the capacitor is placed outside the encapsulation and connected to the free ends of the pins.

In this way, the resistor remains close to the substrate and can be cooled through it. At the same time, the capacitor outside the encapsulation is no longer subject to the severe thermal and mechanical stresses, and can therefore be sized normally.

The invention may also comprise one or more of the following optional characteristics, in any technically possible combination.

Preferably, the power module further comprises a printed circuit board extending out of the encapsulation and receiving the free ends of the pins, and the capacitor is secured to the printed circuit board and connected by the latter to the free ends of the pins.

Preferably also, the printed circuit board carries a control circuit for the electrical component.

Preferably also, the power module further comprises a so-called positive terminal and a so-called negative terminal secured respectively to two of the electrical conductive tracks and adapted to present a DC voltage therebetween, and the resistor and capacitor are connected together between the positive terminal and the negative terminal.

Preferably also, the encapsulation is made of resin.

Preferably also, the electrical component is a semiconductor electrical component.

Preferably also, the power module comprises several semiconductor electrical components forming a switching arm.

An aircraft comprising a power module according to the invention is also proposed.

A method of manufacturing a power module according to the invention is also proposed, comprising:
securing the electrical component against at least one of the electrical conductive tracks, the resistor against at least one of the electrical conductive tracks and the bases of the pins to two of the electrical conductive tracks respectively;
encapsulating at least some of the electrical conductive tracks, the electrical component, the resistor and the bases of the pins; and
connecting the capacitor at the free ends of the pins, outside the encapsulation.

Preferably, the encapsulation is carried out by resin transfer moulding.

### BRIEF DESCRIPTION OF THE FIGURES

The invention will be better understood with the aid of the following description, given only by way of example and made with reference to the secured drawings wherein:

FIG. 1 is an electrical diagram of a power module according to the invention,

FIG. 2 is a three-dimensional view of the power module without the printed circuit board and its support,

FIG. 3 is a three-dimensional view of the power module, with the printed circuit board and its support,

FIG. 4 is a cross-sectional view of the power module, and

FIG. 5 is a block diagram of a method for manufacturing the power module.

### DETAILED DESCRIPTION OF THE INVENTION

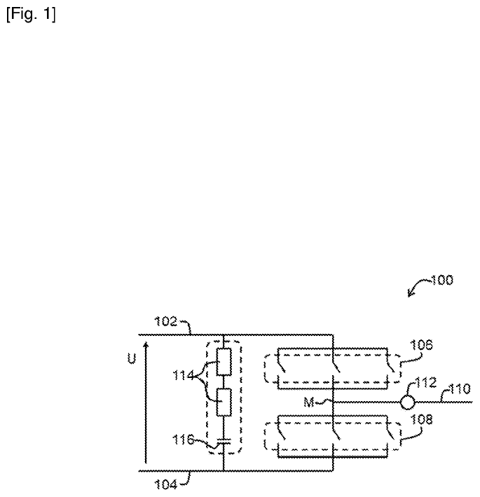

With reference to FIG. 1, an example of a power module 100 according to the invention will now be described.

The power module 100 firstly comprises a positive terminal 102 and a negative terminal 104 designed to present a DC voltage U between them.

The power module 100 also comprises at least one electrical component, for example a semiconductor. For example, the power module 100 implements a switching arm connected between the positive terminal 102 and the negative terminal 104.

The switching arm comprises one or more high-side semiconductor switches 106 in parallel (three in the example shown) and one or more low-side semiconductor switches 108 in parallel (three in the example shown). The high-side switches 106 and the low-side switches 108 are connected to a midpoint M. The power module 100 then further comprises an alternating terminal 110 connected to the midpoint M to provide an alternating voltage.

Each switch 106, 108 is preferably a controllable semiconductor switch, such as a Metal Oxide Semiconductor Field Effect Transistor (MOSFET) or a Silicon Metal Oxide Semiconductor Field Effect Transistor (Si MOSFET) or a Silicon Carbide Metal Oxide Semiconductor Field Effect Transistor (SIC MOSFET) or an Insulated Gate Bipolar Transistor (IGBT) or a Gallium Nitride Field Effect Transistor (GaN FET).

The power module 100 may also include a current sensor 112 on the alternating terminal 110.

The power module 100 also comprises at least one resistor 114 and at least one capacitor 116, connected in series for example between the positive terminal 102 and the negative terminal 104. The resistor 114 and capacitor 116 thus form a passive circuit to assist the switch-over of the switches 106, 108, known as a snubber. The capacitor 116 is used to attenuate overvoltage of the DC voltage U and the resistor 114 is used to dissipate the energy stored in the capacitor 116 and dampen the resonance.

In particular, the capacitor 116 comprises at least one capacitor, for example a ceramic capacitor.

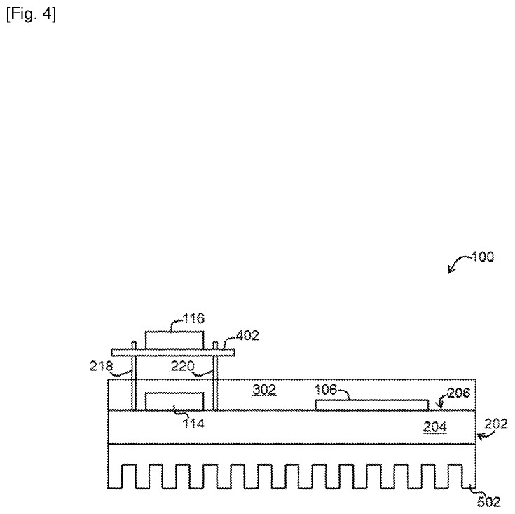

With reference to FIG. 4, the power module 100 comprises a substrate 202 comprising: an electrically insulating plate 204 having an upper face 206, and electrically conductive tracks extending over the upper face 206.

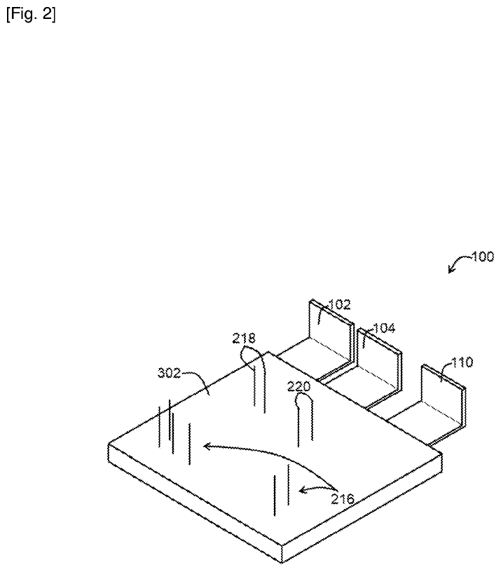

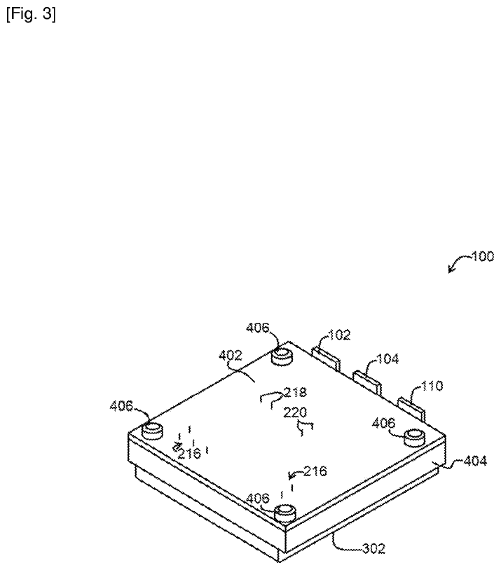

The electrical conductive tracks comprise in particular a so-called positive track to which the positive terminal 102 is secured (for example by soldering), a so-called negative track to which the negative terminal 104 is secured (for example by soldering), a so-called alternative track to which the alternative terminal 110 is secured (for example by soldering), as well as first and second auxiliary tracks. The electrical conductive tracks can also comprise tracks for controlling the switches 106, 108, from which control pins 216 rise (visible in FIGS. 2 and 3).

The high-side switches 106 are thus connected between the positive track and the alternating track. For example, the high-side switches 106 are secured (for example by soldering) against the positive track and connected to the alternating track by conductive wires or ribbon conductors. The low-side switches 108 are connected between the negative track and the alternating track. For example, the low-side switches 108 are secured (for example by soldering) against the alternating track and connected to the negative track by conducting wires or conducting tapes.

In addition, the resistor(s) 114 are connected in series between the first auxiliary track and one of the positive track and the negative track. For example, the first resistor 114 is secured (for example by soldering) to the first auxiliary track and the second auxiliary track and the second resistor 114 is secured (for example by soldering) to the second auxiliary track and the negative track. The resistors 114 are preferably SMT (Surface Mount Technology) components. Alternatively, each resistor 114 could be secured (for example by soldering) to only one of the two electrically conductive tracks and connected to the other by at least one electrically conductive wire or at least one electrically conductive ribbon.

With reference to FIGS. 3 to 5, the power module 100 also comprises at least two pins 218, 220 having bases secured (for example by soldering) to two of the electrical conductive tracks. For example, at least one of the pins 218, 220 has a base secured to one of the positive track and the negative track. For example, at least one other of the pins 218, 220 has a base secured to the first auxiliary track. The pins 218, 220, for example, rise substantially perpendicular to the upper face 206 of the substrate 202.

With reference to FIG. 2, the power module 100 also comprises an encapsulation 302 covering: at least some of the electrical conductive tracks, the switches 106, 108, the resistors 114 and the bases of the pins 216, 218, 220 being covered by the encapsulation 302. The encapsulation 302 is produced by resin transfer moulding, for example, as in the example shown. Alternatively, the encapsulation 302 could comprise a casing, for example glued to the upper face 206 of the substrate 202, this casing being filled with gel.

On the other hand, the free ends of the pins 216, 218, 220 project outside the encapsulation 302.

With reference to FIG. 3, the power module 100 further comprises a printed circuit board 402 extending above the encapsulation and receiving the free ends of the pins 216, 218, 220. The printed circuit board 402 carries, for example, a circuit (not shown) for controlling the switches 106, 108 via the control pins 216.

The power module 100 also comprises, for example, a support 404 for the printed circuit board 402, and screws 406 for securing this support 404 to the substrate 202.

With reference to FIG. 4, the capacitor 116 is secured (for example by soldering) to the printed circuit board 402, outside the encapsulation 302, and connected by the latter to the free ends of the pins 218, 220. Thus, through the use of pins 218, 220, the distance between the capacitor 116 and the resistors 114 can be reduced to a maximum, while maintaining the necessary insulation distances. The capacitor 116 and the resistors 114 are thus connected as close as possible to the power electrical components 106, 108.

In addition, the power module 100 also comprises, for example, a heat sink 502 secured against a lower face 504 of the electrically insulating plate 204 of the substrate 202.

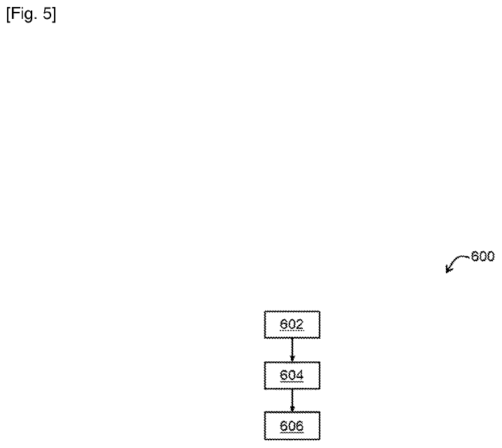

With reference to FIG. 5, an example of a method 600 for manufacturing the power module 100 will now be described.

In a step 602, the switches 106, 108 are secured against the electrical conductive tracks, the resistors 114 are secured against the electrical conductive tracks and the bases of the pins are secured to the electrical conductive tracks respectively.

In a step 604, the encapsulation 302 is carried out, for example by resin transfer moulding.

In a step 606, the capacitor 116 is connected to the free ends of the pins 218, 220, outside the encapsulation 302.

It is clear that a power module such as the one described above allows the use of a snubber with a sufficiently cooled resistor, while using a conventional capacitor. In addition, the placement of the capacitor prevents it from deteriorating during the resin injection from the resin transfer moulding. In fact, during injection, a capacitor soldered onto electrical conductive tracks is subjected to high mechanical stresses due to its size, which can break the solder joints and displace the capacitor.

It will be further noted that the invention is not limited to the embodiments described above. In fact, it will appear to the person skilled in the art that various modifications can be made to the above-described embodiments, in the light of the teaching just disclosed.

In the foregoing detailed presentation of the invention, the terms used should not be interpreted as limiting the invention to the embodiments exposed in the present description, but should be interpreted to include all equivalents the anticipation of which is within the reach of the person skilled in the art by applying his general knowledge to the implementation of the teaching just disclosed.

1. A power module comprising:
a substrate comprising:
an electrically insulating plate having an upper face, and
electrically conductive tracks extending over the upper face;
an electrical component secured against at least one of the electrical conductive tracks;
a resistor secured against at least one of the electrical conductive tracks;
a capacitor connected in series with the resistor; and
an encapsulation covering:
at least a part of the electrical tracks,
the electrical component, and
the resistor;
wherein said power module further comprises:
two pins with:
bases secured to two of the conductive tracks, these bases being covered by the encapsulation, and
free ends projecting outside the encapsulation;
and in that the capacitor is placed outside the encapsulation and connected to the free ends of the pins.

2. The power module of claim 1, further comprising a printed circuit board extending out of the encapsulation and receiving the free ends of the pins, and wherein the capacitor is secured to the printed circuit board and connected by the latter to the free ends of the pins.

3. The power module of claim 2, wherein the printed circuit board carries a control circuit for the electrical component.

4. The power module according to claim 1, further comprising a positive terminal and a negative terminal secured respectively to two of the electrical conductive tracks and adapted to present a DC voltage (U) therebetween, and wherein the resistor and the capacitor are connected together between the positive terminal and the negative terminal.

5. The power module according to claim 1, wherein the encapsulation is made of resin.

6. The power module according to claim 1, wherein the electrical component is a semiconductor electrical component.

7. The power module according to claim 6, comprising several semiconductor electrical components forming a switching arm.

8. An aircraft comprising a power module according to claim 1.

9. A method of manufacturing a power module according to claim 1, comprising:
securing the electrical component against at least one of the electrical conductive tracks, the resistor against at least one of the electrical conductive tracks and the bases of the pins to two of the electrical conductive tracks respectively;
encapsulating at least some of the electrical conductive tracks, the electrical component, the resistor and the bases of the pins; and
connecting the capacitor to the free ends of the pins, outside the encapsulation.

10. The method according to claim 9, wherein the encapsulation is carried out by resin transfer moulding.
